(19) United States
(12) Patent Application Publication
(10) Pub. No.: US 2010/0199914 A1
(43) Pub. Date: Aug. 12, 2010

(54) CHEMICAL VAPOR DEPOSITION REACTOR CHAMBER

(76) Inventor: Michael Iza, Santa Barbara, CA (US)

Correspondence Address: KRAMER & AMADO, P.C., 1725 DUKE STREET, SUITE 240, ALEXANDRIA, VA, 22314, US

(21) Appl. No.: 12/679,870

(22) PCT Filed: May 9, 2008
(86) PCT No.: PCT/US08/05934

§ 371 Date: Mar. 24, 2010

Related U.S. Application Data
(60) Provisional application No. 60/960,691, filed on Oct. 10, 2007.

(51) Int. Cl. C23C 16/00

(52) U.S. Cl. 118/725

(57) ABSTRACT

A chemical vapor deposition reactor is provided which includes a process chamber accommodating a substrate holder for multiple substrates, and a reactor gas inlet which supplies the reactant gases to a portion above the surface of the heated substrates. The reactant gases can be injected parallel or oblique to the substrates and the angle between the supplied reactant gas flow direction and the tangential component of the susceptor's angular rotation is independent of the susceptor's position. A secondary gas inlet which supplies gases perpendicular or at a sharp angle to the substrates is also included so as to change the boundary layer thickness created when hot gases come into contact with the colder reactant gases flowing parallel or oblique to the surface of the substrates.

The present invention relates to a metal organic chemical vapor deposition reactor used for the deposition of a semiconductor crystal film on multiple substrates. The invention is particularly related to a chemical vapor delivery apparatus that promotes high reactant efficiency and uniformity.

### BACKGROUND OF THE INVENTION

Metal Organic Chemical Vapor Deposition (MOCVD) is a standard method for deposition of high quality crystalline thin films used for the fabrication of electronic devices such as light emitting diodes and laser diodes. In general, MOCVD reactors use a metal organic source such as trimethylgallium (TMG) or trimethylindium (TMI) which is then transported by a gas which is inert to the chemical reaction, such as nitrogen or hydrogen, into a chamber. While in the chamber the metal organic compounds are heated, decompose, and then chemically react with a hydride gas, such as ammonia or arsine, to form a thin film on a heated substrate. For example, when TMG and ammonia are injected into a reactor under proper conditions, the resultant chemical reaction forms a film of a simple binary compound, gallium nitride (GaN). The thickness and composition of resulting films can be controlled by adjusting various parameters such as reactor pressure, carrier gas flow rate, substrate rotation speed, temperature, and various other parameters dependent upon reactor design. In addition, since these reactions occur at the substrate's surface, the resulting film properties are highly governed by the flow pattern of the reactant gases over the substrate.

Most multi-wafer MOCVD deposition chambers consist of a single gas injector which directs the reactant gases onto the desired surface, such as a substrate. These configurations result in two types of multi-substrate reactor designs, one in which the substrate is perpendicular to the reactant gas flow, known as the vertical reactor design, and one in which the reactant gas flow is parallel to the substrate surface; known as the horizontal reactor design.

In the vertical multi-wafer design, semiconductor substrates or other objects are mounted on a susceptor disk which rotates about a vertical axis. During growth, cold reactant gases flow downwardly through a passageway toward the substrates. In addition, heat from the susceptor causes gases to rise and form a large non-uniform boundary layer of hot gas over the substrates and susceptor which can extend to the top surface of the reactor chamber. When lower temperature reactant gases come into contact with the hot gases, heat convection can occur. These heat convection effects lead to the formation of a boundary layer which results in a recirculating flow pattern and causes a disturbance of the laminar flow. These disturbances in the laminar flow cause detrimental deposition conditions on the films by changing the uniformity and composition of the deposited thin films across the surface of the substrate.

Another undesirable property of multi-substrate vertical reactors is the adverse effect of deposition of reactants on the surface of the reactant gas injector. Vertical reactors commonly use a fine mesh or other flow distribution device in order to produce a uniform flow pattern into the reactor that is vortex-free. These flow devices often accumulate deposited reactants and disturb the flow pattern over a period of time. Thus, a cleaning procedure needs to be implemented on a regular basis in order to maintain a predictable flow pattern. This results in extensive downtime and wasted productivity of the deposition system.

A metal organic chemical vapor deposition system may also involve a rotating disk reactor in which the substrates are held face down with the rotatable susceptor mounted to the top of the reactor chamber. During growth, the reaction gases are then injected through an injection channel located on one of the chamber side walls or on the bottom wall of the reactor. One disadvantage of this system is that a complex susceptor mechanism needs to be employed with mounting face plates, clamps, clips, adhesives, or other mechanisms in order to hold the substrates in place while being held face down. These mechanisms also disturb the flow pattern of the reactant gases causing non-uniform deposition across the substrate's surface. Another disadvantage of this reactor is that these mechanisms introduce unwanted impurities onto the substrate's surface during growth.

Another disadvantage of this reactor is the formation of particles on the reactant injector. This is due to the formation of particles during growth which accumulate on the susceptor and subsequently fall downwards onto the gas injector located on the bottom of the reactor, disturbing the injected flow pattern. Thus, a cleaning procedure needs to be implemented on a regular basis in order to maintain a predictable flow pattern which results in extensive downtime and wasted productivity of the deposition system.

In a multi-wafer horizontal design the reactor has a single gas reactant injector located in the rotational center of the rotating substrates. It also may comprise a susceptor onto which substrates or other objects are placed and rotated about a central axis by the rotation rod. During growth, cold chemical vapors flow horizontally through a passageway toward the substrates. In addition, heat from the susceptor causes gases to rise and form a large non-uniform boundary layer of hot gas over the substrates and susceptor which can extend to the top surface of the reactor chamber. When lower temperature reactant gases come into contact with the hot gases, heat convection can occur. These heat convection effects lead to the formation of a boundary layer which results in a recirculating flow pattern causing a disturbance of the laminar flow. These disturbances in the laminar flow cause detrimental deposition conditions by changing the uniformity and composition of the deposited thin films across the object's surface, similar to the effects observed in vertical reactor designs. However, these effects are even larger in horizontal reactors for two main reasons. Firstly, since the flow path of the reactant gases is parallel to the substrate, there is no downward flow vector to counterbalance the upward flow vector created by the buoyant effects of the heated gases. This leads to an increase in the thickness of the boundary layer. Secondly, the rotation rate of the susceptor is much less than those of vertical reactors, therefore the gases are not pulled towards the susceptor's surface by the rotation of the susceptor, such as those in a vertical reactor design. These two effects greatly diminish the efficiency of the reactants at the substrate. In addition to the difficulties stated above, current horizontal multi-substrate reactors also suffer from effects caused by parasitic deposition on the reactor walls. These depositions cause detrimental effects on the deposited films including: changing the flow pattern across the substrate's surface, causing temperature fluctuations over time, and causing particles to drop from the surface onto the substrates. Thus, a cleaning procedure needs to be implemented on a regular basis in order to maintain a predictable flow pattern and temperature distribution across the substrate and to remove unwanted deposits in order to prevent particles from falling onto the substrates, which damages the substrates. This results in extensive downtime and wasted productivity of the deposition system.

A MOCVD reactor may use two separate gas injection flows, one flow that injects the chemical reactant vapor parallel to the substrate's surface while the other injection flow presses these vapors closer to the substrate's surface by making their flow perpendicular to the substrate surface. This reactor design has a reactant injector located near one leading edge of the rotating substrate. It may also comprise a susceptor onto which a substrate or other object is placed and rotated about a central axis by the rotation rod. During growth, the reactant gases are injected through the reactant injector and follow a flow path onto the surface of the substrate. A second flow injected by a second injector through a flow channel which is perpendicular to the substrate surface is used to push down the reactant gas flow closer to the substrate. The secondary flow gases are inert to the reaction and therefore do not contribute to the reaction at the substrate's surface.

One disadvantage with the two-flow reactor system as described in the previous paragraphs is that it allows for only one substrate to be deposited at one time. This single substrate design greatly minimizes the commercial applicability of this deposition technique because of its inherently low throughput.

Another disadvantage of this design is that the supplied reactant gases are directed only on one leading edge of the rotating substrate. Thus, the angle between the tangential component of the angular velocity of the rotating substrate and the reactant gas supply direction is dependent on the susceptor's position. This results in high variability of deposition conditions across the substrate's surface which greatly reduces the uniformity of the deposition across the substrate's surface. In addition, disruption of the reactant gas flow pattern due to heat convection from the heated substrate and gas flow interactions with the substrate's surface cause perturbations in the laminar flow of the reactant gases across the substrate's surface because the reactants are injected on one leading edge of the susceptor. These flow perturbations dramatically increase in their effect as the substrate and susceptor increase in size. This greatly limits the size and number of substrates that can be deposited on simultaneously while still maintaining a laminar reactant flow pattern.

A MOCVD horizontal reactor may use a feed gas supplied parallel to the substrate and a forcing gas placed in opposition to the substrate in which the central portion of the forcing gas has a lower flow than in the peripheral portion of the forcing gas.

Another disadvantage of this design is the added complexity of the use of a forcing gas which has multiple flow patterns and velocities. The use of multiple flow patterns causes turbulence to develop at the interfaces between these two flows which significantly affect the flow pattern of the reactant gases across the substrate surface. This results in non-uniform deposition across the substrates and causes inadequate deposition reproducibility.

The foregoing objects and advantages of the invention are illustrative of those that can be achieved by the various exemplary embodiments and are not intended to be exhaustive or limiting of the possible advantages which can be realized. Thus, these and other objects and advantages of the various exemplary embodiments will be apparent from the description herein or can be learned from practicing the various exemplary embodiments, both as embodied herein or as modified in view of any variation which may be apparent to those skilled in the art. Accordingly, the present invention resides in the novel methods, arrangements, combinations, and improvements herein shown and described in various exemplary embodiments.

### SUMMARY OF THE INVENTION

In light of the present need for an improved way of fabricating semiconductor crystals, a brief summary of various exemplary embodiments is presented. Some simplifications and omissions may be made in the following summary, which is intended to highlight and introduce some aspects of the various exemplary embodiments, but not to limit its scope. Detailed descriptions of preferred exemplary embodiments adequate to allow those of ordinary skill in the art to make and use the inventive concepts will follow in later sections.

In various exemplary embodiments, a reactor chamber for coating more than one substrate may comprise a rotatable susceptor which has an angular velocity with a tangential component when rotating; at least two substrates mounted to the susceptor's surface, the susceptor causing these substrates to rotate within the reactor chamber; a heater to heat the susceptor; a first gas injector which supplies reactant gases oblique to a surface of the substrates, wherein the reactant gases flow in a direction to form an angle between that direction and a tangential component of the angular velocity, wherein that angle is independent of a position of the susceptor; a second gas injector which supplies a pushing gas at a sharp angle to the surface of the substrates; and a chamber gas outlet for the reactant gases to exit the reactor chamber.

In various exemplary embodiments, a reactor chamber for coating more than one substrate may comprise at least two susceptors mounted within a reactor chamber; at least one substrate mounted to a surface of the susceptors; means for causing the susceptors to rotate, the rotation of the susceptors causing the substrate to rotate; means for heating the susceptors; a first gas injector which supplies reactant gases oblique to a surface of the substrate which is located approximately equidistant from the susceptors; a second gas injector which supplies a pushing gas at a sharp angle to the surface of the substrate so that a boundary layer caused by heating of the susceptors is compressed; and a chamber gas outlet for the reactant gases to exit the chamber.

In various exemplary embodiments, the susceptor has a rotational center and the first gas injector may be located approximately in the rotational center of the susceptor. The second gas injector may be located approximately above the substrates. The substrates may reside on a heated susceptor and rotate about a common axis which enters the reactor chamber through a hole in the base plate. The susceptor may have dual rotation, rotate mechanically, or operate on gas foil rotation.

In various exemplary embodiments, the reactor may further comprise a peripheral wall that comprises a gate valve to create access to the at least two substrates. Means for heating may be provided beneath the susceptor for heating the susceptor. Reactant gases may exit through ports located on a peripheral wall, a base plate, or a top plate. The reactor chamber may have a top with a center. The reactant gases may enter the reactor chamber through an inlet, wherein this inlet is located approximately in the center of the top of said reactor chamber.

In various exemplary embodiments, the reactor may further comprise a rotation rod connected to the chamber, wherein the susceptor is attached to the rotation rod and the rotation of the rod causes the susceptor to rotate in the chamber. The reactor may further comprise a top plate that is movable with respect to an outer cylindrical ring in an upward direction in order to create free access to the substrates for manipulation of the substrates. The reactor may further comprise a base plate that is movable with respect to an outer cylindrical ring in a downward direction in order to create free access to the substrates for manipulation of the substrates.

In various exemplary embodiments, the rotation rod may be hollow and a surface of the susceptor may have a central inlet in alignment with the rod, wherein reactant gases enter the chamber through the rod and the central inlet. The reactor may further comprise a cylindrical shaped part located above the central inlet that forms an angle with the central inlet. The angle of the cylindrical shaped part may be adjusted to adjust the angle between the inlet and the cylindrical part and the location of the cylindrical shaped part may be adjusted to adjust the distance between the inlet and the cylindrical part.

In various exemplary embodiments, the reactor chamber may further comprise a bottom with a center, wherein reactant gases enter the reactor chamber through an inlet located approximately in the center of the bottom of the reactor chamber. The susceptor may be moved up and down to vary the distance between the heater and the susceptor. The reactor may further comprise a reactant inlet which may be adjusted to adjust the angle between the inlet and the susceptor. The location of said reactant inlet may also be adjusted to adjust the distance between the inlet and the susceptor.

In various exemplary embodiments, the reactor chamber may further comprise a peripheral wall, wherein a reactant gas inlet is located in the peripheral wall, the inlet forming an angle with the susceptor. The susceptor may be moved up and down to change the distance between the heater and the susceptor. The reactant inlet may be adjusted to adjust the angle between the inlet and the susceptor. The location of the reactant inlet may be adjusted to adjust the distance between the inlet and the susceptor.

In various exemplary embodiments, a metal organic chemical vapor deposition (MOCVD) semiconductor fabrication reactor may comprise a susceptor mounted within a MOCVD reactor chamber; at least two substrates mounted to a surface of the susceptor; means for causing the susceptor to rotate, the rotation of the susceptor causing the substrates to rotate; the susceptor having an angular velocity with a tangential component when rotating; means for heating the susceptor; a first gas injector which supplies reactant gases oblique to a surface of the substrates and in which the reactant gases flow in a direction to form an angle between the direction and the tangential component of the angular velocity, wherein the angle is independent of a position of the susceptor; a second gas injector which supplies a pushing gas at a sharp angle to the surface of the substrates so that a boundary layer caused by heating of the susceptor is compressed; and a chamber gas outlet for reactant gases to exit the chamber.

In various exemplary embodiments, the susceptor may have a rotational center and the first gas injector may be located approximately in the rotational center of the susceptor. The second gas injector may be located approximately above the substrates. The susceptor may have dual rotation, rotate mechanically, or operate on gas foil rotation.

In various exemplary embodiments, the reactor chamber may further comprise a peripheral wall having a gate valve to create access to the substrates. The reactor chamber may further comprise a top plate that is movable with respect to an outer cylindrical ring in an upward direction in order to create free access to the substrates for manipulation of the substrates. The reactor chamber may further comprise a base plate that is movable with respect to an outer cylindrical ring in a downward direction in order to create free access to the substrates for manipulation of the substrates.

In various exemplary embodiments, the reactor chamber may further comprise a reactant gas inlet located in a sidewall. The reactor chamber may further comprise a hollow rod and a surface of the susceptor may have a central inlet in alignment with the rod, wherein the reactant gases enter the chamber through the rod and the central inlet.

In various exemplary embodiments, a metal organic chemical vapor deposition (MOCVD) semiconductor fabrication reactor may comprise at least two susceptors mounted within a MOCVD reactor chamber; at least one substrate mounted to a surface of the susceptors; means for causing the susceptors to rotate, the rotation of the susceptors causing the substrate to rotate; means for heating the susceptors; a first gas injector which supplies reactant gases oblique to a surface of the substrate and which is located approximately equidistant from the susceptors; a second gas injector which supplies a pushing gas at a sharp angle to the surface of the substrate so that a boundary layer caused by heating the susceptor is compressed; and a chamber gas outlet for reactant gases to exit the chamber.

In various exemplary embodiments, the second gas injector may be located approximately above the substrate. The susceptors may rotate mechanically or operate on gas foil rotation. The reactor chamber may further comprise a peripheral wall having a gate valve to create access to the substrate. The reactor chamber may further comprise a top plate that is movable with respect to an outer cylindrical ring in an upward direction in order to create free access to the substrate for manipulation of the substrate. The reactor chamber may further comprise a base plate that is movable with respect to an outer cylindrical ring in a downward direction in order to create free access to the substrate for manipulation of the substrate.

Other objects, advantages and novel features of the present invention will become apparent from the following detailed description of the invention when considered in conjunction with the accompanying drawings.

### BRIEF DESCRIPTION OF THE DRAWINGS

In the following, the invention will be explained without a limitation of the general idea of the invention by means of embodiments with reference to the drawing to which explicit reference is made with respect to all inventive details of the invention not explained in the text. The drawings are not necessarily to scale, emphasis instead of being placed upon illustrating the principles of the invention.

FIG. 1 is a schematic of a vertical sectional view of the present invention, in which flow directions of gases are illustrated;

FIG. 2 illustrates a top view of the reactant flow pattern as mentioned in the preferred embodiment of this invention;

FIG. 3a is a schematic of a vertical sectional view of the present invention, in which flow directions of gases are illustrated;

FIG. 3b is a schematic of a susceptor that can be used in the reactor of FIG. 3a;

FIG. 4 is a schematic of a vertical sectional view of the present invention, in which flow directions of gases are illustrated;

FIG. 5 is a schematic of a vertical sectional view of the present invention, in which flow directions of gases are illustrated;

FIG. 6 is a schematic of a reactant gas injector that can be used in the reactor of FIG. 5;

FIG. 7 is a schematic of a vertical sectional view of the present invention, in which flow directions of gases are illustrated; and

FIG. 8 is a schematic of a vertical sectional view of the present invention, in which flow directions of gases are illustrated.

### DETAILED DESCRIPTION

Referring now to the drawings, in which like numerals refer to like components or steps, there are disclosed broad aspects of various exemplary embodiments.

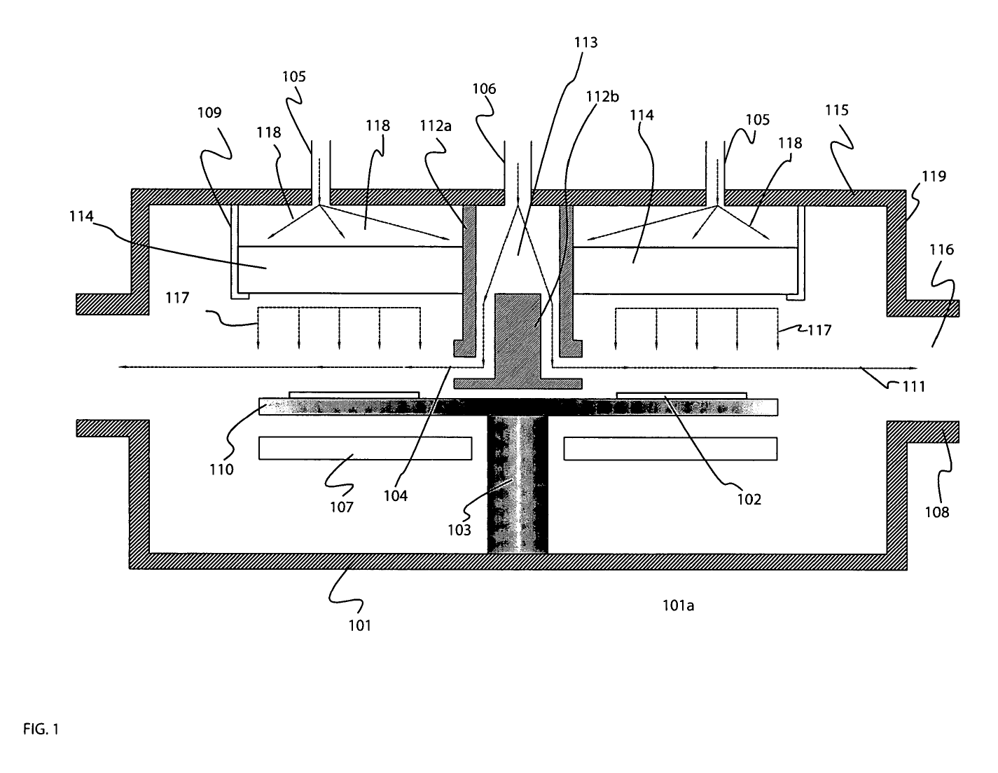

FIG. 1 is a schematic representation of a vertical sectional view of a multi-wafer dual flow MOCVD reactor 101a showing one embodiment of the principles of this invention.

The reactor 101a comprises a cylindrical reactor vessel 101 having a reactant gas injector 112a and 112b, a secondary gas injector 114, and a gas exit or exhaust 116. The reactor is roughly cylindrical having a vertical axis. The reactor may have a circular bottom plate with a diameter of about 60 cm, which in turn supports a rotating substrate holder or susceptor 110, on which more than one substrate or other objects are placed. The susceptor has a rotating axis 103 passing through an opening in the bottom plate which is hermetically sealed. Heating means 107 are disposed beneath the susceptor in order to provide heating to the susceptor which in turn heats the substrates or other objects. Heating can be provided by means of a RF generator or a resistive type heating element. The substrate or other object's holder is made of an appropriate material to accommodate the objects and to be resilient to the process temperature and reactant gases. The holder may be made graphite or silicon carbide coated graphite.

The reactant injector 112a and 112b is located above the susceptor 110 and is situated in the rotational axis of the susceptor. This injector is hermetically sealed to the top plate 115. The injector 112a and 112b can be composed of a metal, such as stainless steel, aluminum, or copper. The injector 112a and 112b can also be composed of material with a low thermal conductivity, such as quartz, polycrystalline aluminum oxide (Al₂O₃), and/or boron nitride. The injector 112a and 112b has a roughly cylindrical shape in which the reactant gases enter through the top portion of the injector and then exit though the bottom portion of the injector 112a and 112b with a flow pattern 104 that is parallel or oblique to the surface of the substrates 102 and in which the angle between the reactant flow direction and the tangential component of the angular velocity of the susceptor's rotation is independent of the susceptor's position. The reactant gas injector is composed of two parts 112a and 112b. Section 112b has a roughly cylindrical shape with two different outer radii. The smaller outer radius fits into 112a and provides spacing between 112a and 112b in order to allow the flow of the reactant gases to flow through this gap in a downward direction. The larger outer radius then directs the flow of the reactant gases in a roughly horizontal direction. The spacing between 112a and 112b can also be composed of concentric tubes centered on the rotational axis of the susceptor. These tubes can allow the uniform distribution of reactant gases exiting the reactant injector. The reactant gases are then allowed to exit through a spacing between 112a and 112b toward the substrates 102 so that the reactant gas flow is parallel or oblique to the surface of the substrates 102 and in which the angle between the reactant flow direction and the tangential component of the angular velocity of the susceptor's rotation is independent of the susceptor's position.

The reactant flow path is directed to flow over the substrates 102 or other objects radially outward from the reactant injector to the outer wall of the cylindrical reactor body 101, eventually exiting through the exhaust ports 116 located on the outer cylinder wall 118. The reactant gases can, for example, be composed of trimethylgallium (TMG), trimethylaluminum (TMA), diethylzinc (DEZ), triethylgallium (TEG), Bis(cyclopentadienyl)magnesium (Cp₂Mg), trimethlyindium (TMI), arsine (AsH₃), phosphine (PH₃), ammonia (NH₃), silane (SiHₐ), disilane (Si₂H₆), hydrogen selenide (H₂Se), hydrogen sulfide (H₂S), methane (CH₄), etc. . . .

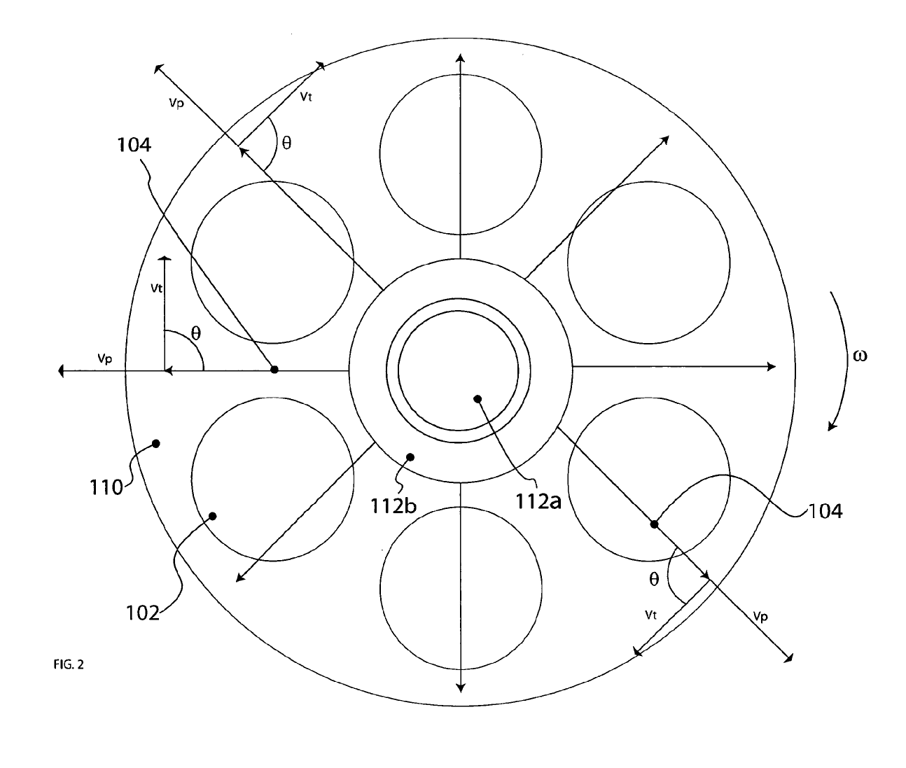

A top view of the reactant flow pattern for an embodiment of this invention is illustrated in FIG. 2. The reactant injector 112a injects the reactant gases in which the angle, θ, between the reactant flow direction 104 and the tangential component, Vt, of the angular velocity, ωs, of the rotating susceptor 110 is independent of the susceptor's position.

By use of a reactor with a reactant injector in which the reactants are supplied in a direction that is parallel or oblique to the substrates and in which the angle between the reactant flow direction and the tangential component of the angular velocity of the susceptor's rotation is independent of the susceptor's position, the reactant gases can deposit uniformly across the entire surface on all substrates simultaneously compared to reactor chambers which have various angles between the reactant flow direction and the tangential component of the angular velocity of the rotating susceptor. This improved reactant injection design improves the uniformity of the deposited reactants on the substrates' surfaces. This improved design also allows for uniform and homogeneous deposition independent of the position of the substrate on the susceptor. This also allows for identical deposition of films on all the substrates positioned on the susceptor's surface.

Referring again to FIG. 1, the secondary gas injector 114 is located above the substrates or other objects at a distance that may be greater than 5 mm, or may be approximately 15 mm, and is held in place by an “L” shaped bracket 109 mounted to the top plate 115 of the reactor chamber. The secondary gas is then injected over the surface of the substrates or other objects and follows a downward flow pattern 117 which is perpendicular or at a sharp angle (for example, 30° or greater) to the substrates' surfaces so as to change the boundary layer thickness created when the hot gases come into contact with the cold reactant gases flowing parallel or oblique (less than a 30° angle) to the surface of the substrates. The hot gas temperature range is from approximately 200 to 1500 degrees Celsius and the cold gas temperature range is from approximately zero to 200 degrees Celsius. The secondary injector gas is supplied by a gas inlet port 105 located on the top plate 115 of the reactor chamber. The secondary gas injector can be composed of a “showerhead” type of design with a pattern of openings on the injector. These openings can also be composed of small holes, slits, concentric circles, a fine wire mesh, or a combination of any of these mechanisms which act to evenly distribute the injected gas in a downward direction perpendicular or at a sharp angle to the surface of the substrates. The secondary injector is located directly above the substrates in order to concentrate the flow of the reactant gases over the surface of the substrates. Since the secondary gas that flows vertically downward to a substrate or other object is used to eliminate the recirculation effects on the reactant gases, all inert gases having no influence on the reaction gas can be used as the pressing gas. Examples of the pressing gas are hydrogen (H₂), nitrogen (N₂), helium (He), neon (Ne), and argon (Ar). These gases can be used singly or as a mixture thereof. The gas injector can be composed of highly insulating materials, such as quartz (SiO₂), polycrystalline aluminum oxide (Al₂O₃), or boron nitride (BN) in order to reduce the thermal boundary layers above the substrates. The gas injector can also be composed of metal with a high thermal conductivity such as aluminum, stainless steel, or copper which is cooled by a circulating fluid coolant such as water and/or ethylene glycol.

By using a secondary gas flow directed perpendicular or at a sharp angle (such as 30° or greater) to the substrate's surface, the depth of the boundary layer can be independently changed compared to reactor chambers that don't employ the use of a secondary gas flow according to the present invention. Accordingly, the thickness of the boundary layer can be optimized for various deposition conditions which allows for the independent control of the gas flow pattern across the surface of the substrates. The manipulation of the boundary layer height reduces the turbulence generated when lower temperature reactant gases come into contact with the boundary layer. The reactant gases can also more easily penetrate the boundary layer which allows for greater reactant efficiency.

The use of a secondary gas flow directed perpendicular or at a sharp angle (such as 30° or greater) to the substrates surface, minimizes the amount of parasitic deposition on reactor surfaces by concentrating the deposition of reactant gases onto the surface of substrates. This minimizes the amount of impurities incorporated on the substrates which can damage the substrates. These unintended deposits also cause reactor deposition conditions such as substrate temperature and chemical vapor flow patterns to change over a period of time. In addition, by minimizing the parasitic deposition on unwanted surfaces, the amount of impurities which fall on and damage the substrates or other objects is drastically reduced. These stated benefits drastically reduce the amount of cleaning and conditioning procedures required in conventional reactor designs.

Use of a secondary gas flow directed perpendicular or at a sharp angle to the substrate's surface in order to control the boundary layer above the substrates and susceptor eliminates the need for mounting face plates, clamps, clips, adhesives, or other complex mechanisms in order to hold the substrates in place if the injector configuration requires the substrates to be held face down. These complex mechanisms disturb the flow pattern of the reactant gases causing non-uniform deposition across the substrates' surface. In addition, the use of these complex mechanisms to hold the substrates in place can introduce impurities during the deposition process.

By use of a secondary gas flow which is composed of one velocity, the turbulence generated at the interface of multiple gas velocities by using a secondary gas injector with two or more gas velocities can be eliminated. Any turbulence in the gas flow patterns causes deleterious effects in the deposition of reactants on substrates by creating unstable transient flow patterns which affect the uniformity and the reproducibility of the deposited films.

By use of the a secondary gas flow directed perpendicular or at a sharp angle to the substrates surface in combination with a reactor design mechanism that allows for the deposition of crystal layers on more than one substrate or other object, the throughput of the reactor and thus the total output productivity per deposition step can be greatly increased. A further advantage of this reactor design is the ability to easily scale the reactor components in order to accommodate various numbers of substrates without changing the overall design of the reactor components. This allows for greater flexibility in the manufacture of these systems for various customized applications.

The reactor's top plate 115 which includes the reactant gas injector 112a and 112b and the secondary gas injector 114 is hermetically sealed to the main reactor side walls 119 by a rubber o-ring located on the outer diameter of the reactor vessel. This allows for access to the reactor by removing the top plate in order to replace the substrates or other objects after a deposition step has been completed. Thus, substrates or other objects can be replaced on an as-needed basis. The reactors outer walls are composed of stainless steel and can be fluid cooled by a circulating fluid such as water and/or ethylene glycol.

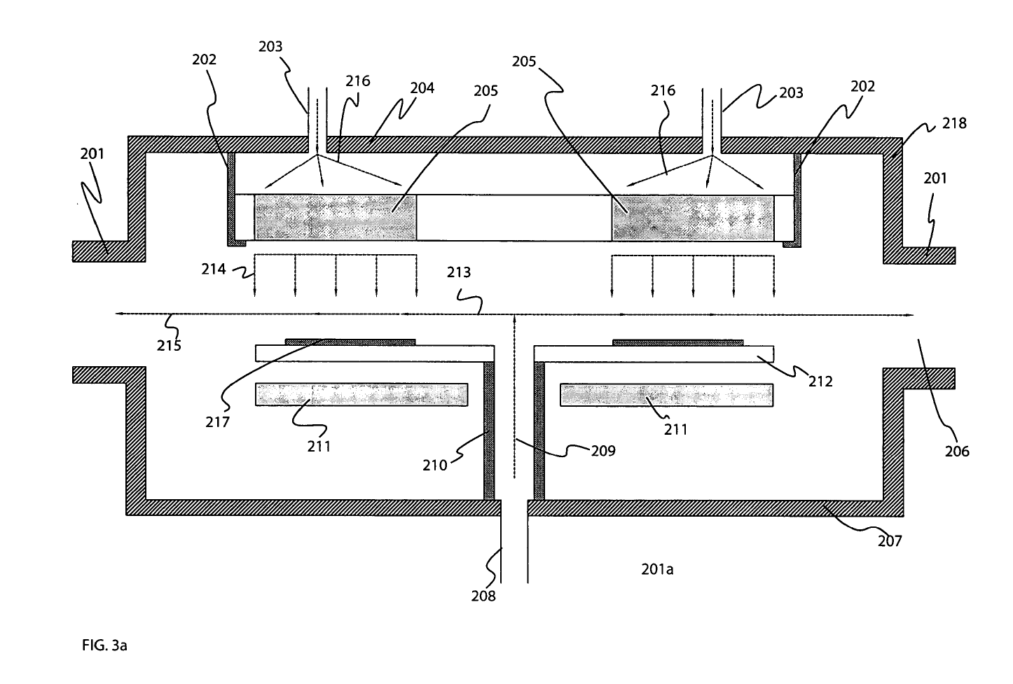

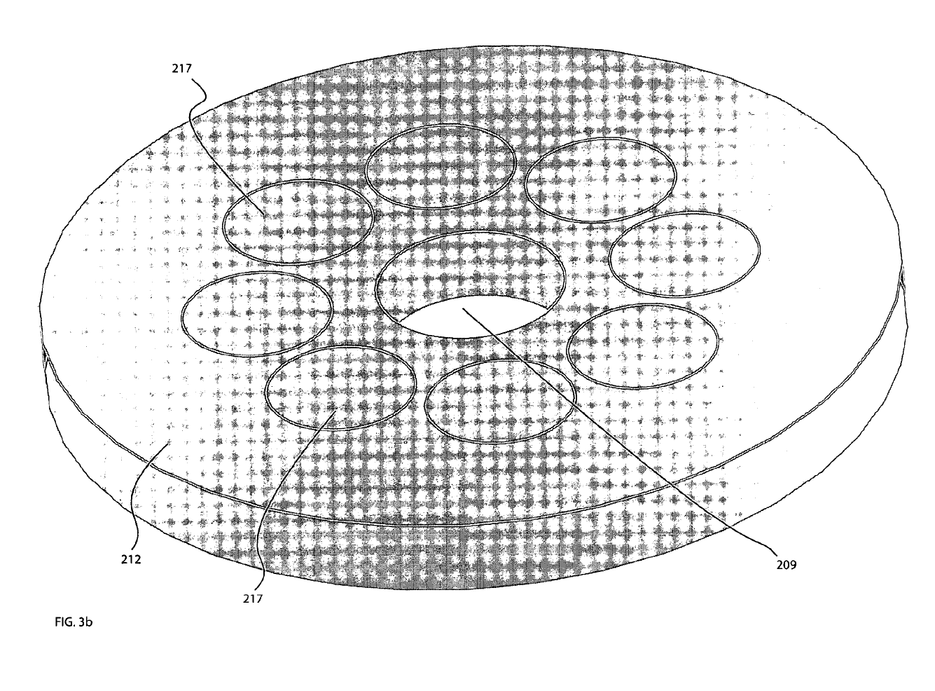

FIG. 3a shows another embodiment of an MOCVD reactor 201a in accordance with the present invention, where the reactor has a hollow rotation rod 210 so that reactant gases can enter the reactor chamber through the rotation rod.

FIG. 3b shows a susceptor that can be used in reactor 201a. As shown in FIG. 3a, the reactor 201a has a center gas inlet 208 that includes a gas inlet 209 through the rotation rod 210 and the susceptor 212. This gas inlet 209 allows for the reactant gases to be injected into the reactor. While the susceptor is rotating, the reactant gases enter through the bottom of the rotation rod and are directed to the top of the rotation rod and through the opening in the susceptor. These reactant gases are then drawn towards the rotating substrates 217 as indicated by arrow 213, with a flow that is parallel or oblique (less than 30)° to the substrates and in which the angle between the reactant flow direction and the tangential component of the angular velocity of the susceptor's rotation is independent of the susceptor's position, and deposit some material on the substrates. This reactant flow design incurs the same benefits as stated above in accordance with the present invention. Like above, the reactant gases are pushed closer to the substrates by the secondary flow 214 which is directed perpendicular or at a sharp angle (30° or greater) to the surface of the substrates. This secondary flow is injected as described above, with a secondary gas injector 205 located above the substrates. Reactants that do not deposit are directed to the chamber's outer walls as indicated by arrow 215 and exit through the exhaust ports 201 located on the side walls 218 of the reactor chamber. This secondary flow incurs the same benefits as stated above in accordance with the present invention.

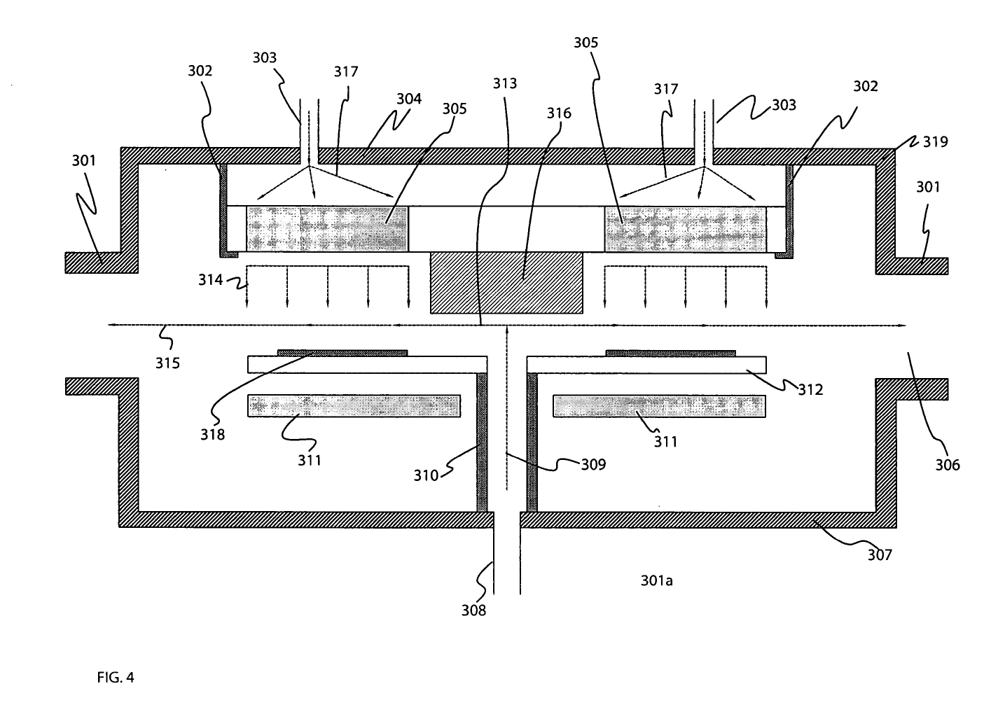

FIG. 4 shows another embodiment of an MOCVD reactor 301a in accordance with the present invention, where the reactor has a hollow rotation rod so that reactant gases can enter the reactor chamber through the rotation rod. The susceptor of FIG. 3b can be used in reactor 301a.

The reactor 301a which includes a center gas inlet 309 that includes a gas inlet 308 through the rotation rod 310 and the susceptor 312. Like the embodiment in FIG. 3a this gas inlet 309 allows for the reactant gases to be injected into the reactor. While the susceptor is rotating, the reactant gases enter through the bottom of the rotation rod and are directed to the top of the rotation rod and through the opening in the susceptor. In addition an adjustable cylindrical disk 316 located above the opening in the susceptor further aids these reactant gases to be directed towards the rotating substrates with a flow 313 that is parallel or oblique to the substrates 318, and in which the angle between the reactant flow direction and the tangential component of the angular velocity of the susceptor's rotation is independent of the susceptor's position, and deposit some material on the substrates. This reactant flow design incurs the same benefits as stated above in accordance with the present invention. Like the embodiment of FIG. 1, the reactant gases are also pushed closer to the substrates by the secondary flow 314 which is directed perpendicular or at a sharp angle to the surface of the substrates. This secondary flow is injected as described for the embodiment of FIG. 1, with a secondary gas injector 305 located above the substrates. Reactants that do not deposit are directed to the chamber's outer walls as indicated by path 315 and exit through the exhaust ports 301 located on the side walls 319 of the reactor chamber. This secondary flow incurs the same benefits as stated above in accordance with the present invention.

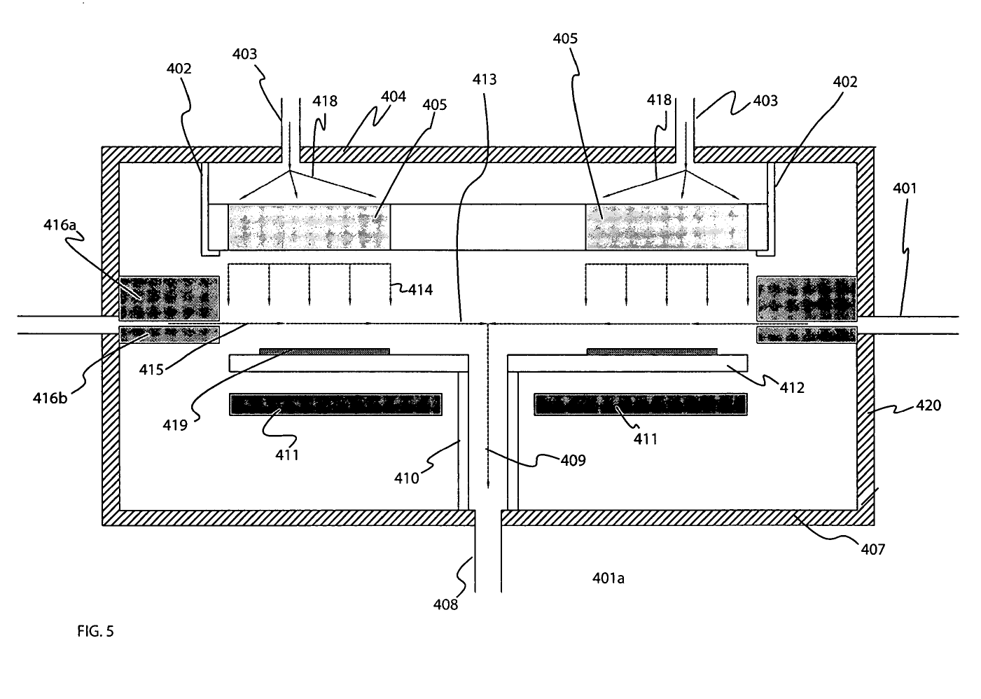

FIG. 5 shows another embodiment of an MOCVD reactor 401a in accordance with the present invention, where the reactor has a reactant injector 416a and 416b that is located on the side walls 420 of the reactor chamber 401a and has a hollow rotation rod 410 so that exhaust gases can exit the reactor chamber through the rotation rod.

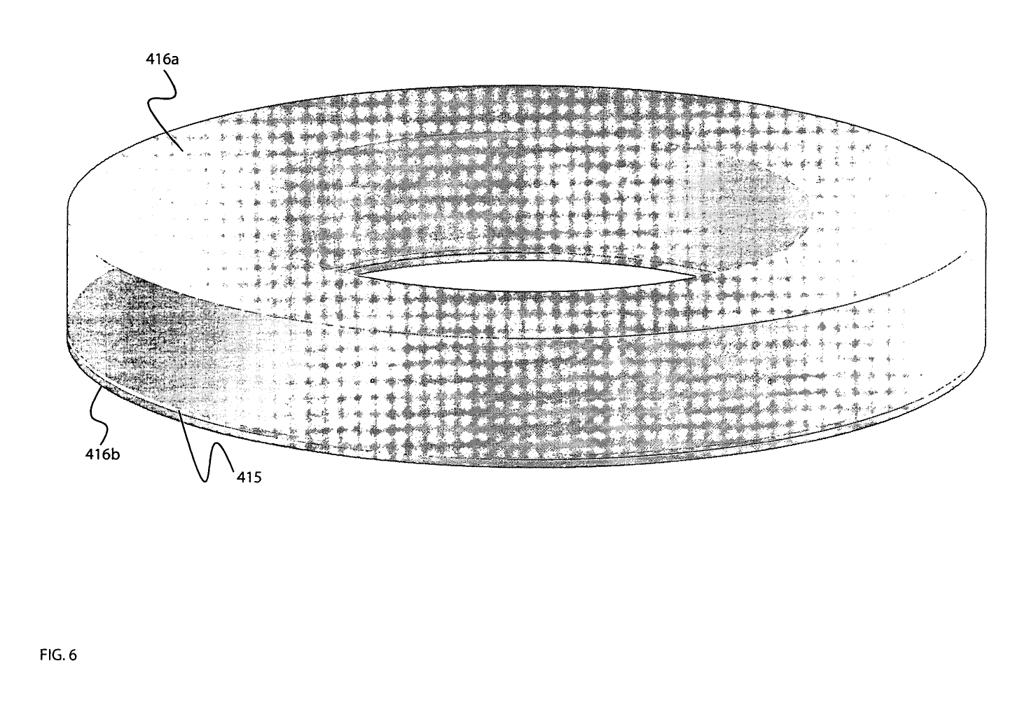

FIG. 6 shows an injector that can be used in reactor 401a which includes a cylindrical shaped inlet mounted to the side wall of the reactor chamber. This inlet is composed of two parts 416a and 416b which have a circular ring shape. These parts are mounted so that a small opening between the two parts allows for the flow of reactant gases into the reactor chamber. This opening can also be composed of small holes, slits, concentric circles, a fine wire mesh, or a combination of any of these mechanisms which act to evenly distribute the injected reactant gas flow in a direction that is parallel or oblique to the surface of the substrates and in which the angle between the reactant flow direction and the tangential component of the angular velocity of the susceptor's rotation is independent of the susceptor's position, as described for the embodiment in FIG. 1. This reactant flow design incurs the same benefits as stated above in accordance with the present invention. As described for the embodiment of FIG. 1, the reactant gases in FIG. 5 are pushed closer to the substrates by the secondary flow 414 which is directed perpendicular or at a sharp angle to the surface of the substrates. This secondary flow is injected as described for the embodiment of FIG. 1, with a gas injector 405 located above the substrates. Reactants that do not deposit are directed through the opening in the susceptor and rotation rod and exit through the exhaust port 408 located on the bottom 407 of the reactor chamber. This secondary flow incurs the same benefits as stated above in accordance with the present invention.

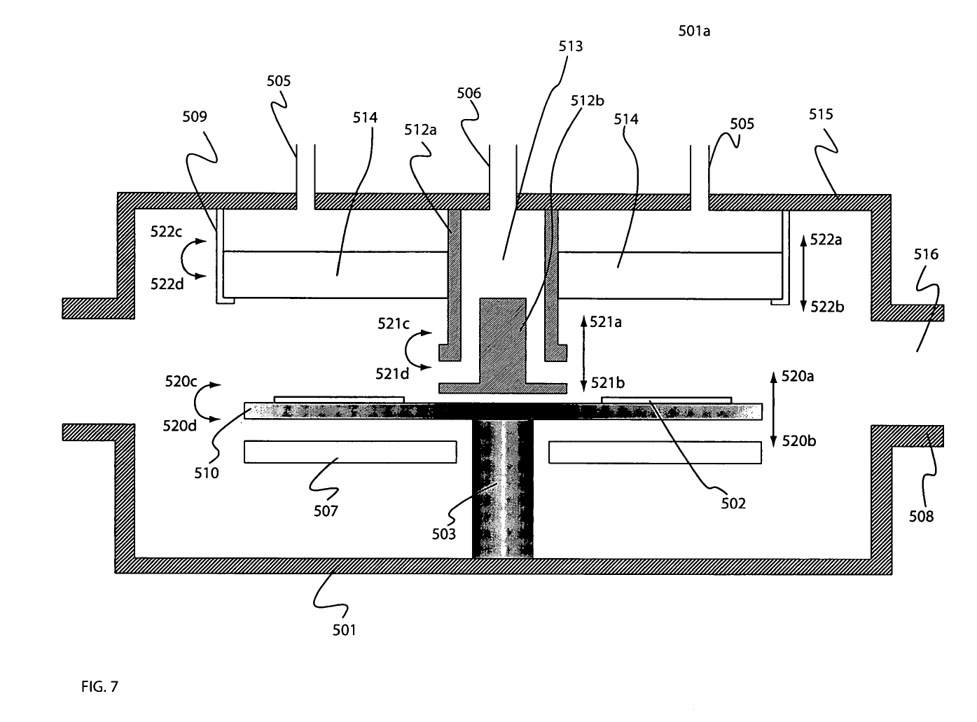

FIG. 7 shows still another embodiment of an MOCVD reactor 501a in accordance with the present invention, which includes a rotating susceptor, a reactant gas inlet, a secondary gas inlet, substrates on the susceptor, and a heater, all of which are similar to those of the reactor shown in FIG. 1. In most respects the reactor 501a functions in the same way as reactor 101a in FIG. 1. However, in reactor 501a the susceptor is mounted to the bottom of the reactor 501 by a rod 503 that is movable in the directions shown by arrows 520a, 520b, 520c, and 520d to adjust the distance and angle between the heater 507 and the susceptor 510. That is, the susceptor 510 can move vertically in the directions indicated by 520a and 520b. The susceptor 510 can also move or tilt angularly as indicated by arrows 520c and 520d, preferably at an angle of +/−15 degrees. This adjustment can vary the amount of heat that is coupled to the susceptor 510 in order to adjust the temperature distribution across the susceptor in order to vary the temperature profile of the susceptor and the substrates that are held atop the susceptor. The rotating susceptor is operated by a stepper motor or the like which is computer controlled.

As further shown in FIG. 7, the reactant gas injector 512a and 512b can also be adjusted in the direction of arrows 521a, 521b, 521c, and 521d in order to vary the distance and angle between the susceptor 510 and the reactant gas injector 512a and 512b. That is, injector 512b can be adjusted vertically by the operator as indicated by arrows 521a and 521b. Further, the injector 512a and 512b can be adjusted angularly as in the direction indicated by arrows 521c and 521d, preferably at an angle of +/−15 degrees. Both sections 512a and 512b can angle/tilt and can move up and down independently. These adjustments can vary the semiconductor deposition conditions of the substrates held atop of the susceptor 510. In addition, the secondary gas injector 514 can also be adjusted in the direction of the arrows 522a, 522b, 522c, and 522d in order to vary the distance and angle between the secondary gas injector 514 and the susceptor 510. That is, the secondary gas injector 514 can be adjusted vertically in the directions indicated by arrows 522a and 522b. Further, the secondary gas injector 514 can be titled at an angle as indicated by arrows 522c and 522d preferably at angle of +/−15 degrees. These adjustments can also vary the semiconductor deposition conditions of the substrates held atop of the susceptor 510. All of these moving parts can be moved or tilted by adjustable screws but can also be moved/tilted by a stepper motor which is computer controlled.

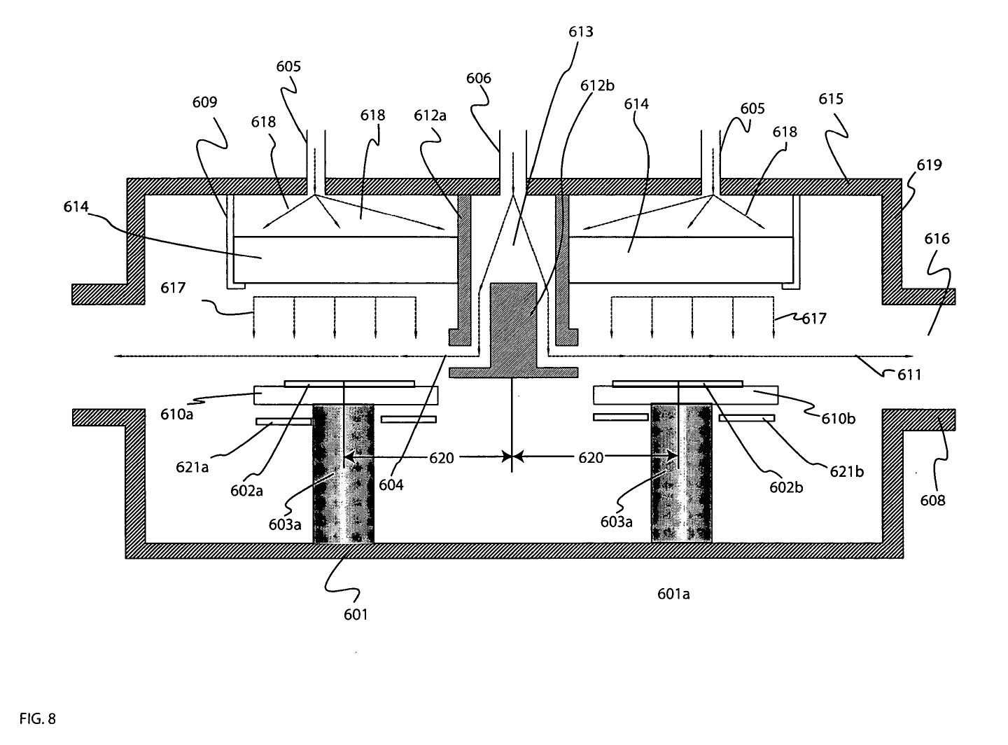

FIG. 8 shows still another embodiment of an MOCVD reactor 601a in accordance with the present invention, which includes a reactant gas inlet and a secondary gas inlet, all of which are similar to those of the reactor shown in FIG. 1. In most respects, the reactor 601a functions in the same way as reactor 101a in FIG. 1. However, in reactor 601a the single susceptor is replaced by at least two rotating susceptors 610a and 610b, each susceptor holding at least one substrate. The at least two susceptors are located approximately equidistant 620 from the reactant gas inlet 612a and 612b. By use of a reactor with a reactant injector in which the reactants are supplied in a direction that is parallel or oblique to the substrates and in which the reactant injector is located equidistant to the rotating at least two rotating susceptors, the reactant gases can deposit uniformly across the entire at least one substrate surface on all susceptors simultaneously compared to reactor chambers which have the reactant injector at various distances with the rotating susceptors. This improved reactant injection design improves the uniformity of the deposited reactants on the substrates's surfaces. This improved design also allows for uniform and homogeneous deposition independent of the position of the substrate on the susceptor. This also allows for identical deposition of films on all of the substrates positioned on the susceptor's surface. Additionally, by locating the reactant injector in this way, the use of a dual rotation susceptor can be eliminated. This greatly simplifies the susceptor design which greatly minimizes cost and complexity of the reactor parts.

The movable susceptor arrangement and angle adjustable susceptor described here with respect to FIG. 7 can also be used in reactors 201a (FIG. 3a), and 301a (FIG. 4), reactors that have a reactant gas inlet through the susceptor. The movable secondary gas inlet arrangement and angle adjustable secondary gas inlet can also be used in reactors 201a (FIG. 2), 301a (FIG. 4), 401a (FIG. 5), and 601a (FIG. 8). The movable reactant gas inlet arrangement and angle adjustable reactant gas inlet can also be used in reactor 401a (FIG. 5) and 601a (FIG. 8). The reactors can also include only one or all of these adjustment options.

Although the present invention has been described in considerable detail with reference to certain preferred configurations thereof, other versions are possible. Many different gas inlets, gas outlets, and susceptors can be used. The gas inlets and outlets can be arranged in many different locations. The reactor according to the invention can be used to grow many different semiconductor crystals from many different material systems.

Although the various exemplary embodiments have been described in detail with particular reference to certain exemplary aspects thereof, it should be understood that the invention is capable of other embodiments, and its details are capable of modifications in various obvious respects. As is readily apparent to those skilled in the art, variations and modifications can be affected while remaining within the spirit and scope of the invention. Accordingly, the foregoing disclosure, description, and figures are for illustrative purposes only, and do not in any way limit the invention, which is defined only by the claims.

1. A reactor chamber for coating more than one substrate, comprising:
a rotatable susceptor which has an angular velocity with a tangential component when rotating;
at least two substrates mounted to a surface of said susceptor, said susceptor causing said substrates to rotate within said reactor chamber;
means for heating said susceptor;
a first gas injector which supplies reactant gases oblique to a surface of said substrates,
wherein said reactant gases flow in a direction to form an angle between said direction and said tangential component of said angular velocity,
wherein said angle is independent of a position of said susceptor;
a second gas injector which supplies a pushing gas at a sharp angle to said surface of said substrates; and
a chamber gas outlet for said reactant gases to exit said reactor chamber.

2. A reactor chamber for coating at least one substrate, comprising:
at least two susceptors mounted within said reactor chamber;
at least one substrate mounted to a surface of said susceptors;
means for causing said susceptors to rotate, the rotation of said susceptors causing said substrate to rotate;
means for heating said susceptors;
a first gas injector which supplies reactant gases oblique to a surface of said substrate, wherein said first gas injector is located approximately equidistant from said susceptors;
a second gas injector which supplies a pushing gas at a sharp angle to the surface of said substrate; and
a chamber gas outlet for said reactant gases to exit said chamber.

3. The reactor of claim 1, wherein said susceptor has a rotational center and said first gas injector is located approximately in said rotational center of said susceptor.

4. The reactor of claim 1, wherein said second gas injector is located approximately above said substrates.

5. The reactor of claim 1, wherein said substrates reside on a heated susceptor and rotate about a common axis.

6. The reactor of claim 1, wherein said susceptor is a susceptor with dual rotation which rotates mechanically.

7. The reactor of claim 1, wherein said susceptor is a susceptor with dual rotation which operates on gas foil rotation.

8. The reactor of claim 1, further comprising a peripheral wall that employs a gate valve to create access to said substrates, said peripheral wall further comprising a reactant gas inlet, said inlet forming an angle with said susceptor.

9. The reactor of claim 1, wherein said means for heating said susceptor is provided beneath said susceptor.

10. The reactor of claim 1, wherein said reactant gases exit through ports located on a peripheral wall, said peripheral wall being movable with respect to an outer cylindrical ring in an upward direction in order to create free access to said substrates for manipulation of said substrates.

11. The reactor of claim 1, wherein said reactant gases exit through ports located on a base plate, said base plate being movable with respect to an outer cylindrical ring in an upward direction in order to create free access to said substrates for manipulation of said substrates.

12. The reactor of claim 1, wherein said reactant gases exit through ports located on a top plate, said top plate being movable with respect to an outer cylindrical ring in an upward direction in order to create free access to said substrates for manipulation of said substrates.

13. The reactor of claim 1, wherein said reactor chamber further comprises a top with a center, wherein said reactant gases enter said reactor chamber through an inlet located approximately in said center of said top of said reactor chamber.

14. The reactor of claim 1, further comprising a rotation rod connected to said chamber, wherein said susceptor is attached to said rotation rod and rotation of said rotation rod causes said susceptor to rotate in said chamber in alignment with said rod, wherein said reactant gases enter said chamber through said rod.

15. The reactor of claim 14, wherein said rotation rod is hollow and wherein a surface of said susceptor further comprises a central inlet in alignment with said rod, wherein said reactant gases enter said chamber through said rod and said central inlet.

16. The reactor of claim 15, further comprising a cylindrical part located above said central inlet defining an angle with said central inlet, wherein said angle can be adjusted to adjust a distance between said central inlet and said cylindrical part.

17. The reactor of claim 1, wherein said reactor chamber further comprises a bottom with a center, wherein said reactant gases enter said reactor chamber through an inlet located approximately in said center of said bottom of said reactor chamber.

18. The reactor of claim 1, wherein said susceptor can be moved up and down to vary a distance between said means for heating said susceptor and said susceptor.

19. The reactor of claim 1, further comprising a reactant inlet which can be adjusted to adjust an angle and a distance between said inlet and said susceptor.

20. The reactor of claim 1, wherein the second gas injector is a showerhead injector which evenly distributes the pushing gas by injecting said pushing gas through a pattern of openings on the second gas injector.

21. The reactor of claim 2, wherein the second gas injector is a showerhead injector which evenly distributes the pushing gas by injecting said pushing gas through a pattern of openings on the second gas injector.
